(19) United States
(12) Patent Application Publication
(10) Pub. No.: US 2024/0186547 A1
(43) Pub. Date: Jun. 6, 2024

(54) FUEL CELL VIRTUAL SENSOR

(71) Applicant: Woodward, Inc., Fort Collins, CO (US)

(72) Inventors: Yi Han, Fort Collins, CO (US); Gregory James Hampson, Boulder, CO (US)

(21) Appl. No.: 18/530,070

(22) Filed: Dec. 5, 2023

Related U.S. Application Data
(60) Provisional application No. 63/430,530, filed on Dec. 6, 2022.

(51) Int. Cl. H01M 8/0444; G01R 31/378; G01R 31/392; H01M 8/04089; H01M 8/04111; H01M 8/04119; H01M 8/04223; H01M 8/0438; H01M 8/04537; H01M 8/04746; H01M 8/04992

(52) U.S. Cl. CPC H01M 8/04455; G01R 31/378; G01R 31/392; H01M 8/04097; H01M 8/04111; H01M 8/04156; H01M 8/04231; H01M 8/04388; H01M 8/04395; H01M 8/04574; H01M 8/04761; H01M 8/04992; H01M 2008/1095

(57) ABSTRACT

The subject matter of this specification can be embodied in, among other things, a method that includes determining an electrical current output of a fuel cell stack configured to generate electrical current from hydrogen provided in a hydrogen recirculation loop, determining an efficiency level of the fuel cell stack, determining a nitrogen diffusion rate based on the determined electrical current output and the determined efficiency level, and determining a nitrogen concentration in the hydrogen recirculation loop based on the determined nitrogen diffusion rate.

### CROSS-REFERENCE TO RELATED APPLICATIONS

This application claims the benefit of priority to U.S. Application No. 63/430,530, filed on Dec. 6, 2022, the contents of which are hereby incorporated by reference.

### TECHNICAL FIELD

This instant specification relates to control systems for hydrogen fuel cells, more particularly, systems and techniques for estimating nitrogen concentrations in a hydrogen recirculation loop.

### BACKGROUND

In most PEM (Proton Exchange Membrane) fuel cells, nitrogen is diffused through the membrane and “crosses-over” to the anode side due to the high concentration of nitrogen (N₂) on the cathode (oxygen, O₂) side of the membrane. This cross-over nitrogen thus dilutes the hydrogen (H₂) concentration in the anode/hydrogen recirculation loop (HRL) by taking up space in the membrane that would otherwise be available for hydrogen, reducing the hydrogen concentration and blocking sites for hydrogen to undergo the electro-chemical reactions that generate electrons and drive hydrogen ions into the membrane. As the nitrogen accumulates, it has detrimental effect on the fuel cell efficiency and power output of the fuel cell.

A standard practice used in existing fuel cell systems is to purge the HRL of the nitrogen when the nitrogen concentration gets too high (e.g., some references say that a 7% nitrogen concentration is the limit). In some prior solutions, purges are performed on a timed interval. However, hydrogen makes up the majority of the gas in the HRL which is purged with the nitrogen. Such purges result in a loss of significant amounts of hydrogen and thus represent an efficiency loss for the fuel cell. Some estimates put the loss of hydrogen due to typical purging at 2%-7%.

Some solutions implement the use of physical sensors to measure nitrogen levels in the HRL in order to determine when a purge is needed. However, such sensors require physical exposure to the gasses in the HRL, and thus require undesirable penetrations of the HRL. Such sensors also add cost, complexity, and potential failure points (e.g., sensor failures, hydrogen leaks) to such systems.

### SUMMARY

In general, this document describes control systems for hydrogen fuel cells, more particularly, systems and techniques for estimating nitrogen concentrations in a hydrogen recirculation loop.

In a general example, a process for estimating nitrogen levels in fuel cells includes determining an electrical current output of a fuel cell stack configured to generate electrical current from hydrogen provided in a hydrogen recirculation loop, determining an efficiency level of the fuel cell stack, determining a nitrogen diffusion rate based on the determined electrical current output and the determined efficiency level, and determining a nitrogen concentration in the hydrogen recirculation loop based on the determined nitrogen diffusion rate.

Various implementations can include some, all, or none of the following features. The process can include determining that the determined nitrogen concentration has exceeded a predetermined nitrogen concentration threshold level and purging the hydrogen recirculation loop based on the determined exceeding of the predetermined nitrogen concentration threshold level. The efficiency can be determined based on the determined nitrogen concentration. Determining a nitrogen concentration in the hydrogen recirculation loop based on the determined nitrogen diffusion rate can include determining an integral of the determined nitrogen diffusion rate over time, wherein the determined nitrogen concentration can be based on the determined integral. The determined nitrogen diffusion rate can be based on a predetermined nitrogen coefficient value, a predetermined membrane pressure gradient value, and a predetermined diffusion concentration value. The process can include controlling a recirculation flow rate of hydrogen based on the determined electrical current output. The process can include flowing the hydrogen and recirculation gasses from the hydrogen recirculation loop through a jet pump configured to urge flow of the recirculation gasses based on the flow of hydrogen. The process can include operating at least one of a water separator or a nitrogen separator based on the determined nitrogen concentration.

In another general example, a fuel cell control system includes first circuitry configured to determine an electrical current output of a fuel cell stack configured to generate electrical current from hydrogen provided in a hydrogen recirculation loop, second circuitry configured to determine an efficiency level of the fuel cell stack, third circuitry configured to determine a nitrogen diffusion rate based on the determined electrical current output and the determined efficiency level, and fourth circuitry configured to determine a nitrogen concentration in the hydrogen recirculation loop based on the determined nitrogen diffusion rate and provide a purge signal based on the nitrogen concentration and a predetermined nitrogen concentration threshold value.

Various embodiments can include some, all, or none of the following features. The fuel cell control system can include fifth circuitry configured to determine that the determined nitrogen concentration has exceeded a predetermined nitrogen concentration threshold level, and provide a purge signal based on the determined exceeding of the predetermined nitrogen concentration threshold level, and a valve configured to selectably permit and prevent purging of the hydrogen recirculation loop based on the purge signal. The efficiency can be determined based on measured current and voltage which is modulated by the determined nitrogen concentration (e.g., if the voltage is lower than expected for a given current, the difference can be ascribed to the dilution effect). The fourth circuitry can be configured to determine an integral of the determined nitrogen diffusion rate over time, wherein the determined nitrogen concentration is based on the determined integral. The determined nitrogen diffusion rate can be based on a predetermined nitrogen coefficient value, a predetermined membrane pressure gradient value, and a predetermined diffusion concentration value. The fuel cell control system can include a current sensor configured to provide a current feedback signal representative of the electrical current output to the first circuitry, an anode pressure sensor configured to provide an anode gas pressure feedback signal representative of an anode gas pressure at an anode manifold of the fuel cell stack to the third circuitry, a cathode pressure sensor configured to provide a cathode gas pressure feedback signal representative of a cathode gas pressure at a cathode manifold of the fuel cell stack to the third circuitry, wherein the determined efficiency level is based on the anode gas pressure and the cathode gas pressure, and a controllable purge valve configured to controllably permit and prevent gas flow out of the hydrogen recirculation loop in response to the purge signal. (we can also control the recirculation flow rate to mitigate N₂ build up effects to extend the purge time)The fuel cell control system can include a hydrogen inlet configured to receive pressurized hydrogen, at least a portion of a hydrogen recirculation loop, a loop outlet configured to fluidically connect the hydrogen recirculation loop to an anode inlet of an anode manifold of a fuel cell stack, and a loop inlet configured to fluidically connect the hydrogen recirculation loop to an anode outlet of the anode manifold. The fuel cell control system can include a jet pump configured to urge flow of gasses from the loop inlet to the loop outlet based on a flow of pressurized hydrogen from the hydrogen inlet (or recirculation blower/pump). The fuel cell control system can include a water separator configured to controllably permit and prevent flow of water out of the recirculation loop based on a water purge signal.

The systems and techniques described here may provide one or more of the following advantages. First, a system can provide increased efficiency of hydrogen consumption by a fuel cell. Second, the system can determine nitrogen and water concentration in one or both of an anode or a hydrogen recirculation loop. Third, the system can operate without nitrogen concentration sensors, water concentration sensors, or hydrogen concentration sensors.

The details of one or more implementations are set forth in the accompanying drawings and the description below. Other features and advantages will be apparent from the description and drawings, and from the claims.

### DESCRIPTION OF DRAWINGS

FIG. 1 is a schematic diagram that shows an example of a fuel cell system.

FIG. 2 is flow chart that shows an example of a process for controlling a fuel cell system.

FIG. 3 is a schematic diagram of an example of a generic computer system.

### DETAILED DESCRIPTION

This document describes systems and techniques for estimating nitrogen concentrations in hydrogen recirculation loops (HRL) of hydrogen-based PEM (Proton Exchange Membrane) fuel cells. As a fuel cell operates, hydrogen is supplied to the anode side of the fuel cell. Nitrogen (N₂) from the ambient atmosphere exists in high concentrations on the cathode side of the fuel cell, and diffuses (e.g., crosses over) the membrane to the anode side during operation, taking up space that would otherwise be available for hydrogen. This reduction in hydrogen concentration causes a corresponding reduction in fuel cell efficiency. In order to recover the lost efficiency, the concentration of nitrogen has to be reduced. Typically, this is done by purging (e.g., flushing) the HRL, but this process also causes an amount of hydrogen to be lost, which incurs an overall efficiency loss of its own. As such, it is desirable to perform such purging only when necessary. For example, some references suggest that an approximately 7% concentration of nitrogen should be considered as a limit.

This document describes systems and techniques that can be used to estimate the nitrogen concentration in the HRL without the use of physical sensors. In general, the systems described in this document measure a current output and efficiency of a fuel cell stack to estimate a nitrogen diffusion (e.g., crossover) rate, and then totalize (e.g., sum, integrate) that estimated amount over time to determine an estimated amount of nitrogen that has diffused into the HRL. When the estimated nitrogen concentration exceeds a predetermined level, a purge operation can be triggered to reduce the nitrogen concentration to near zero, the totalization can be reset to zero, and the process can start over again. As such, unnecessary purging can be avoided, efficiency can be kept high, and the use of dedicated nitrogen sensors in the HRL can be avoided.

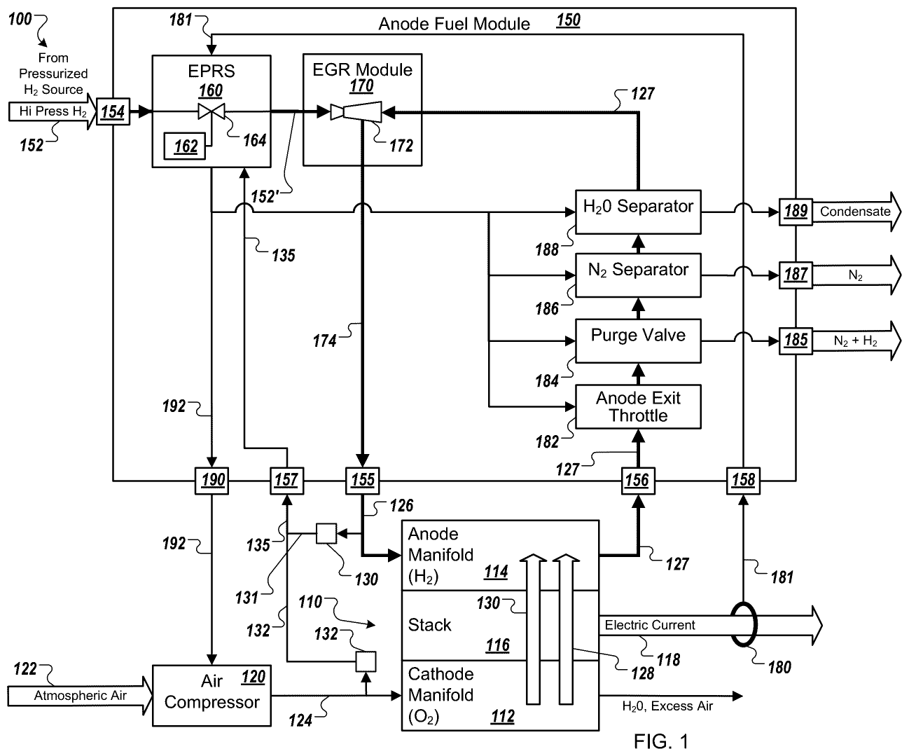

FIG. 1 is a schematic diagram that shows an example of a fuel cell system 100. The example fuel cell system 100 includes a fuel cell 110 having a cathode manifold 112 and an anode manifold 114 separated by a stack 116. In the illustrated example, the fuel cell 110 is a hydrogen-based PEM (Proton Exchange Membrane) fuel cell. An air compressor 120 compresses atmospheric air 122 containing atmospheric oxygen (O₂) and provides pressurized air 124 to the cathode manifold 112. Pressurized hydrogen (H₂) 126 is provided to the anode manifold 114 by an anode fuel module 150.

At the anode manifold 114, the hydrogen 126 diffuses to an anode catalyst and dissociates into protons and electrons. The protons are conducted through a proton-exchange membrane to the cathode manifold 112, and the electrons are forced to travel as an electrical current 118 out through an external circuit. During the catalytic process, oxygen molecules react with the electrons (that traveled through the external circuit) and the protons, resulting in the formation of water.

The atmospheric air 122 is not pure oxygen. It is mostly (e.g., about 78%) nitrogen, with about 21% oxygen and small amounts of other gasses. Atmospheric air also includes water vapor. During operation of the fuel cell 110, a nitrogen diffusion (represented by arrow 128), otherwise known as nitrogen crossover, occurs in which some of the nitrogen in the relatively nitrogen-rich pressurized air 124 at the cathode manifold 112 diffuses across the stack 116 to the relatively nitrogen-poor pressurized hydrogen 126 at the anode manifold 114. Also during operation of the fuel cell, a water diffusion (represented by arrow 130 ), otherwise known as water crossover, occurs in which some water from atmospheric water vapor and/or water produced by the catalytic process at the cathode manifold 112 diffuses across the stack 116 to the relatively dry pressurized hydrogen 126 at the anode manifold 114. The diffused hydrogen and water, along with excess hydrogen not used by the fuel cell, exits the anode manifold 114 as an exhaust gas 127 that is recirculated back to the anode fuel module 150 so the excess hydrogen can be recycled and re-supplied to the fuel cell 110.

In operation, however, as hydrogen gets recycled, a gradual buildup of nitrogen and water occurs. The space occupied by nitrogen and water in the hydrogen supply lines takes up space that could otherwise be occupied by hydrogen. As the percentages of nitrogen and water increase in the hydrogen supply, the percentage of hydrogen drops. Since the operation of the fuel cell 110 is based on hydrogen, a drop in the amount of available hydrogen can cause a corresponding drop in electrical output (e.g., current, voltage) and fuel cell efficiency. Some references identify 7% nitrogen concentration can be an approximate limit, beyond which fuel cell efficiency may drop to an unacceptable level, and/or hydrogen starvation can occur which can damage the fuel cell 110.

The percentage or ratio of hydrogen in the supply can be increased by decreasing the percentage or amount of nitrogen and water in the supply. In general, this is typically accomplished by purging the supply by opening a condensate valve to release separated water, and/or by opening a gas purge valve to vent or otherwise flush nitrogen out of the supply. However, since even at a 7% nitrogen concentration, the hydrogen concentration is still approximately 93%, a purge of the supply causes a significant loss of hydrogen that could otherwise be used to fuel the fuel cell 110. As such, excessive or premature purging can result in an excessive reduction in fuel cell efficiency. Some estimates have it that about 2%-7% of system hydrogen may be lost due to the purging processes used in some previous systems.

In general, the anode fuel module 150 is configured to provide hydrogen to the fuel cell 110, recirculate excess hydrogen from the fuel cell 110, and purge nitrogen from the recirculation gasses in a way that reduces or minimizes excessive loss of hydrogen, thereby increasing or maximizing the efficiency of the fuel cell 110. In general, the anode fuel module 150 performs this process without directly sensing or measuring nitrogen levels in the recirculation gasses, as such sensors can be costly (e.g., rugged enough to survive in a high-pressure hydrogen environment for extended lengths of time) and can create unwanted points for potential failure (e.g., such sensors can fail, and can require penetrations of the pressurized hydrogen circuit that can fail). In general, the anode fuel module 150 performs its purging processes based on a “virtual” nitrogen sensor that estimates nitrogen buildup in recirculation gasses by observing the behavior of the fuel cell 110 over time.

The anode fuel module 150 is configured to receive pressurized hydrogen 152 from a pressurized hydrogen source, such as a storage tank or compressor, at an inlet 154. An electronic pressure regulator system (EPRS) 160 includes controller module 162 configured to control a pressure regulator 164 to controllably regulate the pressure and/or flow of the pressurized hydrogen 152 as a regulated flow of hydrogen 152′.

An exhaust gas recirculation (EGR) module 170 includes a jet pump 172 configured to urge recirculation flow of the exhaust gas 127 (e.g., from the fuel cell 110) based on the flow of the hydrogen 152′ from the EPRS 160. In the illustrated example, controller module 162 can control the rate of gas recirculation through the EGR module 170 by controlling the flow of the hydrogen 152′ to the jet pump 172.

A gas mixture 174 of the hydrogen 152′ and the recirculated exhaust gas 127 is provided to an outlet 155 of the anode fuel module 150. The outlet 155 is configured to provide a removable fluid connection between the anode fuel module 150 and an anode inlet of the anode manifold 114 (e.g., or an intermediary fluid conduit in fluid communication with an inlet of the anode manifold) so the gas mixture 174 can be provided to the anode manifold 114 as fuel for the fuel cell 110. The exhaust gas 127 flows to an inlet 156 configured to provide a removable fluid connection between an anode outlet of the anode manifold 114 and the anode fuel module 150 (e.g., or an intermediary fluid conduit in fluid communication with the exhaust of the anode manifold). Fluid conduits configured to convey the gas mixture 174 and the exhaust gas 127 within the anode fuel module partly define a hydrogen recirculation loop (e.g., with the fuel cell 110 and connecting fluid conduits defining additional parts of the loop).

An anode pressure sensor 130 is configured to sense and measure the anode gas pressure of the gas mixture 174 within the anode manifold 114 and provide an anode gas pressure feedback signal 131 representative of the gas pressure within the anode manifold 114. A cathode pressure sensor 132 is configured to sense the cathode gas pressure of the pressurized air 124 within the cathode manifold 112 and provide a cathode gas pressure feedback signal 133 representative of the gas pressure within the cathode manifold 112. A pressure differential feedback signal 135, based on a difference between the anode gas pressure feedback signal 131 and the cathode gas pressure feedback signal 133 is determined and is provided to an input 157 of the anode fuel module 150. The pressure differential feedback signal 135 is provided to the EPRS module 160. The EPRS module 160 is configured to determine an efficiency of the stack 116 based on the pressure differential feedback signal 135 (e.g., based at least in part on a rate of hydrogen consumption by the stack 116, as indicated by the pressure differential feedback signal 135).

In the illustrated example, the pressure differential feedback signal 135 is determined external to the anode fuel module 150. In some embodiments, the anode pressure sensor 130, the cathode pressure sensor 132, and/or circuitry configured to determine the pressure differential feedback signal 135 can be included as part of, or an accessory to, the fuel cell 110. For example, the fuel cell 110 can provide the pressure differential feedback signal 135 as part of its OEM functionality, or the differential pressure-sensing capabilities can be provided as add-on kit. In some embodiments, the anode pressure sensor 130, the cathode pressure sensor 132, and/or circuitry configured to determine the pressure differential feedback signal 135 can be included as part of the anode fuel module 150. For example, the input 157 can be configured to receive the anode gas pressure feedback signal 131 and the cathode gas pressure feedback signal 133 separately, and both signals can be provided to the EPRS module 160, or the anode fuel module 150 can include a differential circuit configured to determine the pressure differential feedback signal 135 within the anode fuel module 150.

A current sensor 180 is configured to sense and measure the electric current 118 and provide an electric current feedback signal 181 representative of the electric current 118 to an input 158 of the anode fuel module 150. The EPRS module 160 is configured to receive the electric current feedback signal 181 And determine an efficiency of the stack 116 based on the current feedback signal. In some embodiments, the current sensor 180 can be a voltage sensor, and the EPRS module 160 can be configured to receive or determine voltage output of the example fuel cell 110 and determine an efficiency of the stack 116 based on the voltage.

The anode fuel module 150 of the example fuel cell 110 includes an anode exit throttle valve 182 configured to be controlled by the EPRS module 160 to control pressure and/or flow of the exhaust gas 127. A purge valve 184 is configured to be controlled by the EPRS module 160 to selectably open and close, selectably permitting and preventing flow (e.g., venting, purging) of the exhaust gas 127 out through an outlet 185. The anode fuel module 150 includes a nitrogen separator 186 configured to be controlled by the EPRS module 160 to separate nitrogen from the exhaust gas 127 and flow the separated nitrogen to an outlet 187.

A water separator 188 is configured to be controlled by the EPRS module 160 to separate water (e.g., condensate) from the exhaust gas 127 and flow it out though an outlet 189. In some embodiments, the EPRS module 160 can be configured to sense, monitor, estimate, or otherwise determine an amount of water in the exhaust gas 127 and/or the gas mixture 174, and control the water separator 188 to control a humidity level in the gas mixture 174. For example, fuel cell efficiency can be degraded by having an excessive amount of water in the mixture (e.g., taking up space from hydrogen), and the membranes used in some fuel cell stacks can be damaged or degraded if they are allowed to become too dry. As such, the EPRS module 160 can be configured to maintain water/humidity to within a predetermined range.

The anode fuel module 150 includes a port 190 configured to communicatively connect the EPRS module 160 to the air compressor 120. The EPRS module 160 is configured to provide a control signal 192 to control the air compressor 120 to control the pressure and/or flow of the pressurized air (e.g., to control the pressure within the cathode manifold 112).

In operation, the EPRS module 160 flows the gas mixture 174 to the fuel cell 110 and determines an estimated nitrogen diffusion rate into the exhaust gas 127. The diffusion rate is estimated by monitoring the electric current feedback signal 181 and the pressure differential feedback signal 135. EPRS module 160 then monitors (e.g., integrates) the estimated diffusion rate over time to determine an estimated total amount of nitrogen that has diffused into the hydrogen recirculation loop partly defined by the anode fuel module 150 and the fuel cell 110. In some implementations, the determination of the estimated total amount of nitrogen can be treated as a “virtual” nitrogen level sensor. When the estimated total nitrogen value reaches a predetermined purge threshold, the purge controller executes a purge. In some implementations, this process can help prevent excessive or unnecessary nitrogen purging that can release more hydrogen than is completely necessary.

The nitrogen estimation (e.g., virtual sensor) is based on a physics-based mathematical function that uses the electric current feedback signal 181 and the pressure differential feedback signal 135 (e.g., a measurement of the pressure difference across the membrane of the fuel cell 110) to compute the nitrogen cross-over rate (Rn2=dN2/dt) into the hydrogen recirculation loop, and an integrator keeps track of the nitrogen accumulation over time.

In some implementations, the nitrogen accumulation function can be represented as:

$${N}_{2} ( time since last purge ) = \int \frac{{dN}_{2}}{dt} dt = \int {Rn}_{2} ( i , dP , etc . ) dt$$

Where,

Rn₂(i, dP, etc.) =function of current (i), pressure difference across the membrane (dP=P_{cathode}−P_{anode}), the pressure in the anode (to establish the mixture concentration), and other factors which influence the cross-over rate, such as temperature, humidity, or combinations of these and any other appropriate factors.

When the nitrogen accumulation integral reaches a predetermined threshold level, a signal is sent to the purge valve 184 to initiate a purge. When a purge is performed, the integral representing the N₂ accumulation level is reset to zero or to a predetermined nominal “empty” value.

Water accumulation can also be tracked by the EPRS module 160, and water can be added or subtracted via opening and closing condensation and humidification circuits. But when a nitrogen purge is performed, the water accumulation valve can also be reset to zero or to a predetermined nominal value.

In a more detailed example, the nitrogen accumulation at time t can be given as:

N₂[t]=∫₀^{t}Rco_{N2}dt

Where Rco=diffusion or crossover rate.

The nitrogen diffusion (e.g., cross-over) rate can be given as:

$${Rco}_{{N}_{2}} = {∝}_{{N}_{2}} \cdot {D}_{N 2 , O 2 , H 2 O} \cdot \frac{d [ {N}_{2} ]}{dx} + γ \cdot Δ {P}_{C - A} + β \cdot {P}_{C}$$

Where:
α_{N2}=a predetermined tuning factor for nitrogen,
D=diffusion rate,
γ=a predetermined tuning factor for the fuel cell membrane pressure gradient,
B=a predetermined tuning factor for diffusion concentration,
P_{A}=anode pressure, and
P_{C}=cathode pressure.

N₂@=0

N₂@L=(dN₂)/dt·Δt+0.79[Air]

Where L=diffusion distance.

(dN₂)/dt=3.76·dO₂/dt=3.76/2 (dH₂)/dt

(dH₂)/dt=i/(n·F)

Where:

i=total current (amps),

n=2 for hydrogen (H₂)+0.5 oxygen (O₂) (i.e., water), and

F=96,485 coul/mol (Faraday's constant).

Water concentration can also be estimated. In some implementations, the water concentration estimate can be represented as:

$${W}_{v , membrane} = {M}_{v} {A}_{fc} n ( \frac{{n}_{d} {I}_{st}}{F} - {D}_{w} \frac{{c}_{v , ca} - {c}_{v , an}}{{t}_{m}} )$$

Where:
tₘ=membrane thickness, and
cᵥ=water concentration (e.g., assumed to change linearly over membrane thickness).

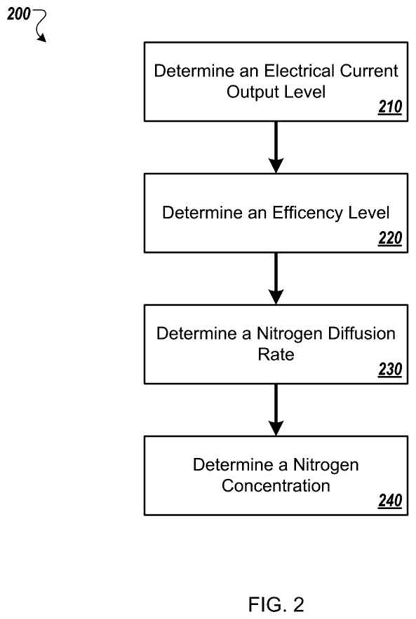

FIG. 2 is a flow chart that shows an example of a process 200 for controlling a fuel cell system. In some implementations, the process 200 can be performed by all or part of the example fuel cell system 100 (e.g., the EPRS module 160).

At 210, an electrical current output of a fuel cell stack configured to generate electrical current from hydrogen provided in a hydrogen recirculation loop is determined. For example, the example controller module 162 of FIG. 1 can measure the electric current 118 output by the fuel cell 110 based on the electric current feedback signal 181 provided by the current sensor 180.

At 220, an efficiency level of the fuel cell stack is determined. In some implementations, determining an efficiency level of the fuel cell stack can include determining a differential pressure across a membrane of the fuel cell stack. In some implementations, determining an efficiency level of the fuel stack can be based on the determined differential pressure. For example, the example controller module 162 can determine the efficiency of the stack 116 based at least in part on the pressure differential feedback signal 135. In another example, the example controller module 162 can estimate the amount of nitrogen that has accumulated in the system based on measurements of current output over time. In another example, the example controller module 162 can measure, determine, or estimate the electrical power (e.g., current, voltage) output by the fuel cell stack as an indicator of efficiency.

At 230, a nitrogen diffusion rate is determined based on the determined electrical current and/or voltage output and the determined efficiency level. For example, the example controller module 162 can estimate an instantaneous rate of the nitrogen diffusion 128 based on the pressure differential feedback signal 135 and the electric current feedback signal 181.

At 240, a nitrogen concentration in the hydrogen recirculation loop is determined based on the determined nitrogen crossover rate. For example, the example controller module 162 can estimate a total amount of nitrogen that has crossed over the example stack 116 based on a totalization (e.g., integral) of the estimation of the nitrogen diffusion 128 over a measured period of time.

In some implementations, the process 200 can include determining that the determined nitrogen concentration has exceeded a predetermined nitrogen concentration threshold level and purging the hydrogen recirculation loop based on the determined exceeding of the predetermined nitrogen concentration threshold level. For example, the controller module 162 can be configured or calibrated with a nitrogen setpoint level of 5%, 6%, 7%, 8%, 9%, or any other value representative of an appropriate maximum concentration of nitrogen for use with the example fuel cell 110, and when the example controller module 162 determines that the estimated nitrogen concentration level has exceeded the setpoint level, the controller module 162 can cause the purge valve 184 to open, at least partly venting the nitrogen-rich exhaust gas 127 and/or gas mixture 174 out the outlet 185, and replace the lost gasses with the substantially pure pressurized hydrogen 152′.

In some implementations, determining the nitrogen concentration in the hydrogen recirculation loop based on the determined nitrogen diffusion rate can include determining an integral of the determined nitrogen diffusion rate over time, wherein the determined nitrogen concentration is based on the determined integral. For example, the example controller module 162 can observe the pressure differential feedback signal 135 and the electric current feedback signal 181 to determine a substantially instantaneous estimate for how fast nitrogen is diffusing into the exhaust gas 127. This diffusion rate estimate can be integrated over time to determine an estimated total amount of nitrogen that has crossed over during that time.

In some implementations, the determined nitrogen diffusion rate can be further based on a predetermined nitrogen coefficient value, a predetermined membrane pressure gradient value, and a predetermined diffusion concentration value.

In some implementations, the process 200 can also include controlling a recirculation flow rate of hydrogen based on the determined electrical current output. For example, the example EPRS module 160 can control the flow of the pressurized hydrogen 152′ to make up for hydrogen that was consumed by the fuel cell 110 and thereby increase the hydrogen concentration based on the estimated total amount of nitrogen in the gas mixture 174 and/or the exhaust gas 127. In some implementations, the process 200 can include flowing the hydrogen and recirculation gasses from the hydrogen recirculation loop through a jet pump configured to urge flow of the recirculation gasses based on the flow of hydrogen. For example, the example EPRS 160 can control the flow of the pressurized hydrogen 152′ to control the degree to which the jet pump 172 urges flow of the exhaust gas 127 into the gas mixture 174 based on the estimated total amount of nitrogen in the gas mixture 174 and/or the exhaust gas 127.

In some implementations, the process 200 can include operating at least one of a water separator or a nitrogen separator based on the determined nitrogen concentration. For example, the example controller module 162 can trigger operation of the example nitrogen separator 186 and/or the water separator 188 based on the estimated total amount of nitrogen in the gas mixture 174 and/or the exhaust gas 127.

In some implementations, the process 200 can include operating a water separator based on an estimated water concentration. For example, the controller 162 can estimate a water diffusion rate and then integrate that crossover rate to determine an estimated total amount of water that has crossed over into the gas mixture 174 and/or the exhaust gas 127. In some implementations, the process 200 can include controlling a water purge based on a predetermined water concentration threshold value and the estimated water concentration. For example, the example controller module 162 can control the example water separator 188 to purge water from the gas mixture 174 and/or the exhaust gas 127 when the concentration exceeds a preset level, in order to reduce the water concentration in the system.

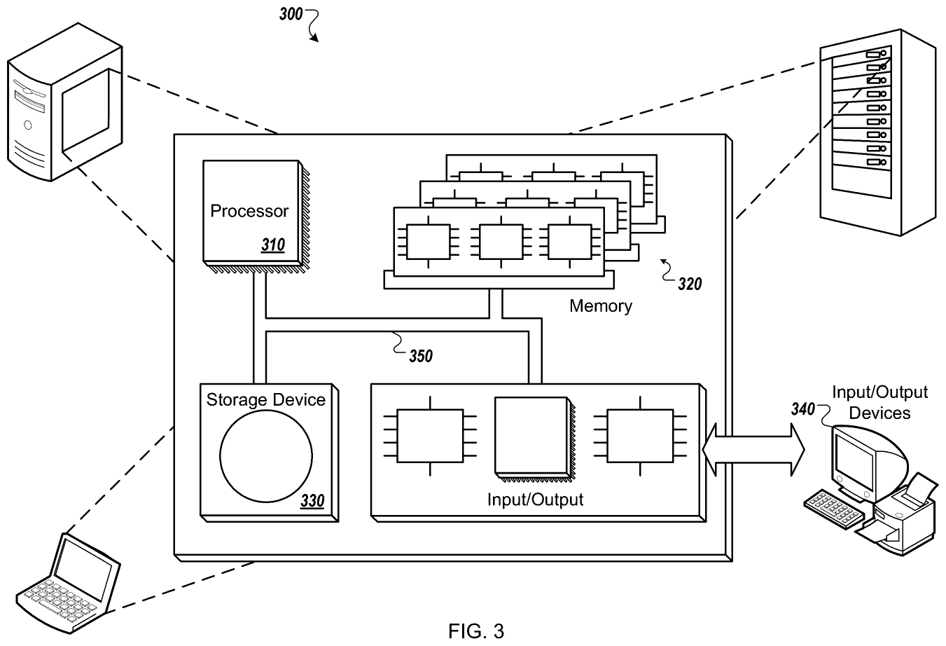

FIG. 3 is a schematic diagram of an example of a generic computer system 300. The system 300 can be used for the operations described in association with the process 200 according to one implementation. For example, the system 300 may be included in either or all of the example EPRS module 160 or the example controller module 162 of FIG. 1.

The system 300 includes a processor 310, a memory 320, a storage device 330, and an input/output device 340. Each of the components 310, 320, 330, and 340 are interconnected using a system bus 350. The processor 310 is capable of processing instructions for execution within the system 300. In one implementation, the processor 310 is a single-threaded processor. In another implementation, the processor 310 is a multi-threaded processor. The processor 310 is capable of processing instructions stored in the memory 320 or on the storage device 330 to display graphical information for a user interface on the input/output device 340.

The memory 320 stores information within the system 300. In one implementation, the memory 320 is a computer-readable medium. In one implementation, the memory 320 is a volatile memory unit. In another implementation, the memory 320 is a non-volatile memory unit.

The storage device 330 is capable of providing mass storage for the system 300. In one implementation, the storage device 330 is a computer-readable medium. In various different implementations, the storage device 330 may be a floppy disk device, a hard disk device, an optical disk device, or a tape device.

The input/output device 340 provides input/output operations for the system 300. In one implementation, the input/output device 340 includes a keyboard and/or pointing device. In another implementation, the input/output device 340 includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier, e.g., in a machine-readable storage device for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random-access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) monitor for displaying information to the user and a keyboard and a pointing device such as a mouse or a trackball by which the user can provide input to the computer.

The features can be implemented in a computer system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include, e.g., a LAN, a WAN, and the computers and networks forming the Internet.

The computer system can include clients and servers. A client and server are generally remote from each other and typically interact through a network, such as the described one. The relationship of client and server arises by virtue of computer programs running on the respective computers and having a client-server relationship to each other.

In some embodiments, some, or all of the functions of the EPRS module 160 and/or the example controller module 162 of FIG. 1, can be implemented as analog circuits, digital circuits, or a combination of both. In some embodiments, the operations of the example process 200 can be implemented as analog circuits, digital circuits, or a combination of both. For example, adders, subtractors, multipliers, dividers, differentiators, integrators, and combinations of these and any other appropriate circuits can be used to perform the functions of the systems and processes described herein.

Although a few implementations have been described in detail above, other modifications are possible. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

What is claimed is:

1. A method for estimating nitrogen levels in fuel cells, the method comprising:
determining an electrical current output of a fuel cell stack configured to generate electrical current from hydrogen provided in a hydrogen recirculation loop;
determining an efficiency level of the fuel cell stack;
determining a nitrogen diffusion rate based on the determined electrical current output and the determined efficiency level; and
determining a nitrogen concentration in the hydrogen recirculation loop based on the determined nitrogen diffusion rate.

2. The method of claim 1, further comprising:
determining that the determined nitrogen concentration has exceeded a predetermined nitrogen concentration threshold level; and
purging the hydrogen recirculation loop based on the determined exceeding of the predetermined nitrogen concentration threshold level.

3. The method of claim 1, wherein the efficiency is determined based on the determined nitrogen concentration.

4. The method of claim 1, wherein determining a nitrogen concentration in the hydrogen recirculation loop based on the determined nitrogen diffusion rate further comprises determining an integral of the determined nitrogen diffusion rate over time, wherein the determined nitrogen concentration is based on the determined integral.

5. The method of claim 1, wherein the determined nitrogen diffusion rate is further based on a predetermined nitrogen coefficient value, a predetermined membrane pressure gradient value, and a predetermined diffusion concentration value.

6. The method of claim 1, further comprising controlling a recirculation flow rate of hydrogen based on the determined electrical current output.

7. The method of claim 6, further comprising flowing the hydrogen and recirculation gasses from the hydrogen recirculation loop through a jet pump configured to urge flow of the recirculation gasses based on the flow of hydrogen.

8. The method of claim 1, further comprising operating at least one of a water separator or a nitrogen separator based on the determined nitrogen concentration.

9. A fuel cell control system comprising:
first circuitry configured to determine an electrical current output of a fuel cell stack configured to generate electrical current from hydrogen provided in a hydrogen recirculation loop;
second circuitry configured to determine an efficiency level of the fuel cell stack;
third circuitry configured to determine a nitrogen diffusion rate based on the determined electrical current output and the determined efficiency level; and
fourth circuitry configured to determine a nitrogen concentration in the hydrogen recirculation loop based on the determined nitrogen diffusion rate and provide a purge signal based on the nitrogen concentration and a predetermined nitrogen concentration threshold value.

10. The fuel cell control system of claim 9, further comprising:
fifth circuitry configured to:
determine that the determined nitrogen concentration has exceeded a predetermined nitrogen concentration threshold level; and
provide a purge signal based on the determined exceeding of the predetermined nitrogen concentration threshold level; and
a valve configured to selectably permit and prevent purging of the hydrogen recirculation loop based on the purge signal.

11. The fuel cell control system of claim 9, wherein the efficiency is determined based on the determined nitrogen concentration.

12. The fuel cell control system of claim 9, wherein the fourth circuitry is further configured to determine an integral of the determined nitrogen diffusion rate over time, wherein the determined nitrogen concentration is based on the determined integral.

13. The fuel cell control system of claim 9, wherein the determined nitrogen diffusion rate is further based on a predetermined nitrogen coefficient value, a predetermined membrane pressure gradient value, and a predetermined diffusion concentration value.

14. The fuel cell control system of claim 9, further comprising:
a current sensor configured to provide a current feedback signal representative of the electrical current output to the first circuitry;
an anode pressure sensor configured to provide an anode gas pressure feedback signal representative of an anode gas pressure at an anode manifold of the fuel cell stack to the third circuitry;
a cathode pressure sensor configured to provide a cathode gas pressure feedback signal representative of a cathode gas pressure at a cathode manifold of the fuel cell stack to the third circuitry, wherein the determined efficiency level is based on the anode gas pressure and the cathode gas pressure; and
a controllable purge valve configured to controllably permit and prevent gas flow out of the hydrogen recirculation loop in response to the purge signal.

15. The fuel cell control system of claim 9, further comprising:
a hydrogen inlet configured to receive pressurized hydrogen;
at least a portion of a hydrogen recirculation loop;
a loop outlet configured to fluidically connect the hydrogen recirculation loop to an anode inlet of an anode manifold of a fuel cell stack; and
a loop inlet configured to fluidically connect the hydrogen recirculation loop to an anode outlet of the anode manifold.

16. The fuel cell control system of claim 15, further comprising a jet pump configured to urge flow of gasses from the loop inlet to the loop outlet based on a flow of pressurized hydrogen from the hydrogen inlet.

17. The fuel cell control system of claim 15, further comprising a water separator configured to controllably permit and prevent flow of water out of the recirculation loop based on a water purge signal.
